(19) United States
(12) Patent Application Publication
(10) Pub. No.: US 2025/0164588 A1
(43) Pub. Date: May 22, 2025

(54) SUPERCONDUCTING MAGNET AND MAGNETIC RESONANCE IMAGING APPARATUS

(71) Applicant: CANON MEDICAL SYSTEMS CORPORATION, Tochigi (JP)

(72) Inventors: Katsutoshi MIZUNO, Nasushiobara (JP); Takehiro SHIBUYA, Nasushiobara (JP); Yoshitomo SAKAKURA, Nasushiobara (JP); Kentaro KIKUCHI, Saitama (JP)

(73) Assignee: CANON MEDICAL SYSTEMS CORPORATION, Tochigi (JP)

(21) Appl. No.: 18/955,956

(22) Filed: Nov. 21, 2024

(30) Foreign Application Priority Data
Nov. 22, 2023 (JP) 2023-198234

(51) Int. Cl. G01R 33/34; H01F 6/06

(52) U.S. Cl. CPC G01R 33/34023; H01F 6/06

(57) ABSTRACT

A superconducting magnet according to an exemplary embodiment is a superconducting magnet used in a magnetic resonance imaging apparatus, and includes a superconducting coil and a cylindrical radiation shield. The superconducting coil is made of a wound superconducting wire material. The radiation shield includes an outer cylinder and an inner cylinder that cover the superconducting coil. The outer cylinder of the radiation shield is made of a metal, and at least a part of the inner cylinder of the radiation shield is made of an insulator or a high-resistance material.

### CROSS-REFERENCE TO RELATED APPLICATIONS

This application is based upon and claims the benefit of priority from Japanese Patent Application No. 2023-198234, filed Nov. 22, 2023, the entire contents of which are incorporated herein by reference.

### FIELD

Exemplary embodiments disclosed in the present specification and drawings relate generally to a superconducting magnet and a magnetic resonance imaging apparatus.

### BACKGROUND

Typically known magnetic resonance imaging (MRI) apparatuses include a superconducting magnet as a static magnetic field magnet configured to generate a static magnetic field in an imaging space where a subject is placed.

The superconducting magnet provided in the MRI apparatus generally includes, in addition to a vacuum container and a superconducting coil, a radiation shield for reducing heat penetration into the superconducting coil.

In such a configuration in which the superconducting magnet provided in the MRI apparatus includes the radiation shield, when a gradient magnetic field coil disposed inside the superconducting magnet is excited, an eddy current occurs in the radiation shield due to a variable magnetic field occurring from the gradient magnetic field coil. The eddy current may cause heat generation in the superconducting coil or result in artifacts in an image.

### BRIEF DESCRIPTION OF THE DRAWINGS

FIG. 1 is a diagram illustrating an exemplary configuration of a magnetic resonance imaging (MRI) apparatus according to a first exemplary embodiment;

FIG. 2 is a diagram illustrating a superconducting magnet according to a comparative example of the first exemplary embodiment;

FIG. 3 is a diagram illustrating an example of a superconducting magnet according to the first exemplary embodiment;

FIG. 4 is a diagram illustrating restriction on a radiation shield according to the first exemplary embodiment;

FIG. 5 is a diagram illustrating restriction on the radiation shield according to the first exemplary embodiment;

FIG. 6 is a diagram illustrating restriction on the radiation shield according to the first exemplary embodiment;

FIG. 7 is a diagram illustrating an example of a radiation shield according to a second exemplary embodiment;

FIG. 8 is a diagram illustrating an example of a radiation shield according to a third exemplary embodiment;

FIG. 9 is a diagram illustrating an example of the radiation shield according to the third exemplary embodiment;

FIG. 10 is a diagram illustrating an example of a radiation shield according to a fourth exemplary embodiment;

FIG. 11 is a diagram illustrating an example of a radiation shield according to a fifth exemplary embodiment;

FIG. 12 is a diagram illustrating an example of a radiation shield according to a sixth exemplary embodiment;

FIG. 13 is a diagram illustrating an example of a radiation shield according to a seventh exemplary embodiment;

FIG. 14 is a diagram illustrating an example of the radiation shield according to the seventh exemplary embodiment;

FIG. 15 is a diagram illustrating an example of a radiation shield according to an eighth exemplary embodiment; and

FIG. 16 is a diagram illustrating an example of the radiation shield according to the eighth exemplary embodiment.

### DETAILED DESCRIPTION

A superconducting magnet according to an exemplary embodiment is a superconducting magnet used in a magnetic resonance imaging apparatus, and includes a superconducting coil and a radiation shield. The superconducting coil is made of a wound superconducting wire material. The radiation shield is formed in a cylindrical shape including an outer cylinder and an inner cylinder, and configured to cover the superconducting coil with the outer cylinder and the inner cylinder. The outer cylinder of the radiation shield is made of a metal, and at least a part of the inner cylinder of the radiation shield is made of an insulator or a high-resistance material.

Various Embodiments will be described hereinafter with reference to the accompanying drawings.

### First Exemplary Embodiment

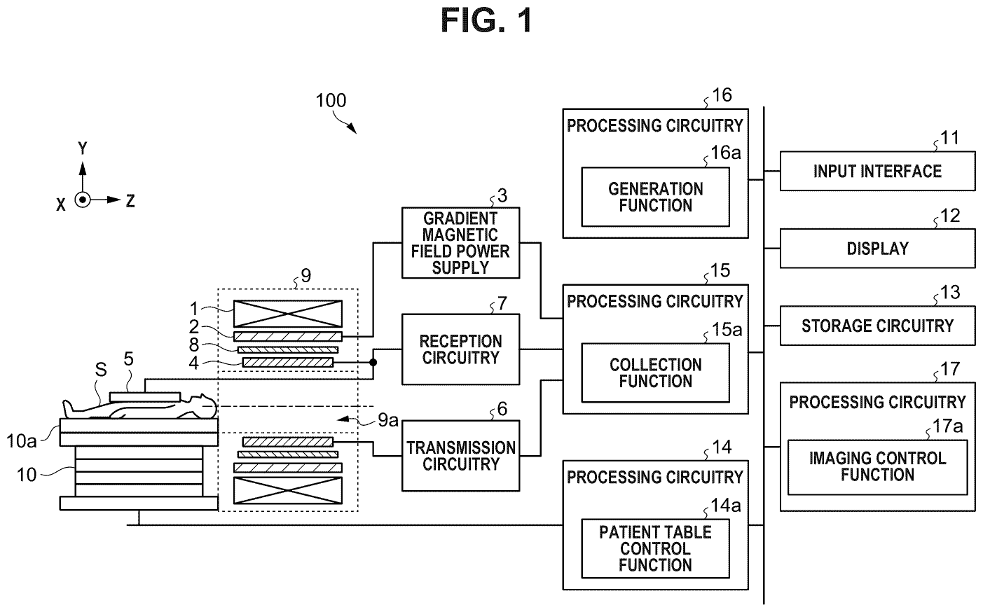

FIG. 1 is a diagram illustrating an exemplary configuration of a magnetic resonance imaging (MRI) apparatus according to a first exemplary embodiment.

For example, as illustrated in FIG. 1, an MRI apparatus 100 includes a static magnetic field magnet 1, a gradient magnetic field coil 2, a gradient magnetic field power supply 3, a whole-body radio frequency (RF) coil 4, a local RF coil 5, transmission circuitry 6, reception circuitry 7, an RF shield 8, a mount 9, a patient table 10, an input interface 11, a display 12, storage circuitry 13, and a plurality of pieces of processing circuitry 14 to 17.

The static magnetic field magnet 1 generates a static magnetic field in an imaging space where a subject S is placed. More specifically, the static magnetic field magnet 1 is formed in a hollow and substantially cylindrical shape (including a shape having the cross-section orthogonal to the central axis of the cylinder is elliptical). The static magnetic field magnet 1 generates a static magnetic field in the imaging space formed on its inner periphery.

The gradient magnetic field coil 2 is disposed inside the static magnetic field magnet 1, and generates a gradient magnetic field in the imaging space where the subject S is placed. More specifically, the gradient magnetic field coil 2 is formed in a hollow and substantially cylindrical shape (including a shape having the cross-section orthogonal to the central axis of the cylinder is elliptical), and includes an X-coil, a Y-coil, and a Z-coil respectively corresponding to an X-axis, a Y-axis, and a Z-axis orthogonal to one another. The X-coil, the Y-coil, and the Z-coil generate gradient magnetic fields that linearly change along the respective axes in the imaging space based on currents supplied from the gradient magnetic field power supply 3. The Z-axis is set to extend along a magnetic flux of the static magnetic field generated by the static magnetic field magnet 1. The X-axis is set to extend along a horizontal direction orthogonal to the Z-axis, and the Y-axis is set to extend along a vertical direction orthogonal to the Z-axis. The X-axis, the Y-axis, and the Z-axis configure an apparatus coordinate system specific to the MRI apparatus 100.

The gradient magnetic field power supply 3 supplies a current to the gradient magnetic field coil 2 to generate the gradient magnetic field in the imaging space. More specifically, the gradient magnetic field power supply 3 individually supplies currents to the X-coil, the Y-coil, and the Z-coil of the gradient magnetic field coil 2, to generate gradient magnetic fields that linearly change along a readout direction, a phase encoding direction, and a slice direction orthogonal to one another, in the imaging space. The axis extending along the readout direction, the axis extending along the phase encoding direction, and the axis extending along the slice direction configure a logical coordinate system for defining a slice region or a volume region to be imaged.

The gradient magnetic fields extending along the readout direction, the phase encoding direction, and the slice direction are superimposed on the static magnetic field generated by the static magnetic field magnet 1, thus imparting spatial positional information to nuclear magnetic resonance (NMR) signals generated from the subject S. More specifically, the gradient magnetic field in the readout direction changes a frequency of the NMR signals based on a position in the readout direction, thus imparting positional information about the readout direction to the NMR signals. The gradient magnetic field in the phase encoding direction changes a phase of the NMR signals based on a position in the phase encoding direction, thus imparting positional information about the phase encoding direction to the NMR signals. In a case where a two-dimensional MR image (slice image) is captured, the gradient magnetic field in the slice direction changes a frequency of the NMR signals based on a position in the slice direction, so that a position, a thickness, and the number of slices to be captured are determined. In a case where a three-dimensional MR image (volume image) is captured, the gradient magnetic field in the slice direction changes the phase of the NMR signals based on the position in the slice direction, thus imparting positional information about the slice direction to the NMR signals.

The whole-body RF coil 4 is disposed on the inner periphery of the gradient magnetic field coil 2, applies RF pulses (e.g., excitation pulses) to the subject S placed in the imaging space, and receives the NMR signals (e.g., echo signals) generated from the subject S by influence of the RF pulses. More specifically, the whole-body RF coil 4 is formed in a hollow and substantially cylindrical shape (including a shape having the cross-section orthogonal to the central axis of the cylinder is elliptical), and applies RF pulses to the subject S placed in the imaging space positioned on the inner periphery thereof, based on RF pulse signals supplied from the transmission circuitry 6. The whole-body RF coil 4 receives the NMR signals generated from the subject S by influence of the RF pulses, and outputs the received NMR signals to the reception circuitry 7. For example, the whole-body RF coil 4 is a birdcage coil or a transverse electromagnetic (TEM) coil.

The local RF coil 5 is disposed near the subject S in imaging, and receives the NMR signals generated from the subject S. More specifically, the local RF coil 5 is prepared for each site of the subject S, is disposed near a site to be imaged when the subject S is imaged, receives the NMR signals generated from the subject S by influence of the RF pulses applied by the whole-body RF coil 4, and outputs the received NMR signals to the reception circuitry 7. For example, the local RF coil 5 is a surface coil, or a phased array coil including a combination of a plurality of surface coils serving as coil elements. The local RF coil 5 may further include a transmission function of applying RF pulses to the subject.

The transmission circuitry 6 outputs, to the whole-body RF coil 4 or the local RF coil 5, an RF pulse signal corresponding to a resonance frequency (Lamor frequency) specific to a target atomic nucleus placed in the static magnetic field. More specifically, the transmission circuitry 6 includes a pulse generator, an RF generator, a modulator, and an amplifier. The pulse generator generates a waveform of an RF pulse signal. The RF generator generates an RF signal of the resonance frequency. The modulator modulates an amplitude of the RF signal generated by the RF generator with the waveform generated by the pulse generator, thereby generating the RF pulse signal. The amplifier amplifies the RF pulse signal generated by the modulator, and outputs the amplified RF pulse signal to the whole-body RF coil 4 or the local RF coil 5.

The reception circuitry 7 generates NMR data based on the NMR signals output from the whole-body RF coil 4 or the local RF coil 5, and outputs the generated NMR data to the processing circuitry 15. More specifically, the reception circuitry 7 includes a selector, a preamplifier, a phase detector, and an analog/digital (A/D) converter. The selector selectively receives NMR signals output from the whole-body RF coil 4 or the local RF coil 5. The preamplifier amplifies the NMR signals output from the selector. The phase detector detects a phase of the NMR signals output from the preamplifier. The A/D converter converts analog signals output from the phase detector into digital signals to generate NMR data, and outputs the generated NMR data to the processing circuitry 15. All the pieces of processing described as processing performed by the reception circuitry 7 are not necessarily performed by the reception circuitry 7, and part of the processing (e.g., processing by A/D converter) may be performed by the whole-body RF coil 4 or the local RF coil 5.

The RF shield 8 is disposed between the gradient magnetic field coil 2 and the whole-body RF coil 4, and shields the gradient magnetic field coil 2 from the RF pulses generated from the whole-body RF coil 4. More specifically, the RF shield 8 is formed in a hollow and substantially cylindrical shape (including a shape having the cross-section orthogonal to the central axis of the cylinder is elliptical), and is disposed in the space on its inner peripheral of the gradient magnetic field coil 2 so as to cover the outer peripheral surface of the whole-body RF coil 4.

The mount 9 includes a hollow bore 9a formed in a substantially cylindrical shape (including a shape having the cross-section orthogonal to the central axis of the cylinder is elliptical), and houses the static magnetic field magnet 1, the gradient magnetic field coil 2, the whole-body RF coil 4, and the RF shield 8. More specifically, the mount 9 houses the whole-body RF coil 4 disposed on an outer peripheral side of the bore 9a, the RF shield 8 disposed on the outer peripheral side of the whole-body RF coil 4, the gradient magnetic field coil 2 disposed on an outer peripheral side of the RF shield 8, and the static magnetic field magnet 1 disposed on the outer peripheral side of the gradient magnetic field coil 2. A space inside the bore 9a included in the mount 9 serves as the imaging space where the subject S is placed in imaging.

The patient table 10 includes a top board 10a on which the subject S is to be placed, and moves the top board 10a on which the subject S is placed, to the imaging space when the subject S is imaged. For example, the patient table 10 is installed such that a longitudinal direction of the top board 10a is parallel to the center axis of the static magnetic field magnet 1.

The input interface 11 receives input operation of various types of instructions and various types of information from an operator. More specifically, the input interface 11 is connected to the processing circuitry 17, converts the input operation received from the operator into an electric signal, and outputs the electric signal to the processing circuitry 17. For example, the input interface 11 is realized by a trackball, a switch button, a mouse, a keyboard, a touch pad through which input operation is performed by touch on the operation surface, a touch screen in which a display screen and a touch pad are integrated, non-contact input circuitry using an optical sensor, audio input circuitry, and the like for performing setting of an imaging condition, a region of interest (ROI), and the like. In the present specification, the input interface 11 is not limited to one including a physical operation part, such as a mouse and a keyboard. For example, electric signal processing circuitry that receives an electric signal corresponding to input operation from an external input device provided separately from the apparatus, and outputs the electric signal to control circuitry is also included in examples of the input interface 11.

The display 12 displays various types of information. More specifically, the display 12 is connected to the processing circuitry 17, converts data on various types of information transmitted from the processing circuitry 17 into electric signals for display, and outputs the electric signals for display. For example, the display 12 is realized by a liquid crystal monitor, a cathode ray tube (CRT) monitor, or a touch panel.

The storage circuitry 13 stores various types of data. More specifically, the storage circuitry 13 is connected to the plurality of pieces of processing circuitry 14 to 17, and stores various types of data input and output by the processing circuitry. For example, the storage circuitry 13 is realized by a semiconductor memory element, such as a random access memory (RAM) and a flash memory, a hard disk, or an optical disk.

The processing circuitry 14 includes a patient table control function 14a. The patient table control function 14a controls operation of the patient table 10 by outputting a control electric signals to the patient table 10. For example, the patient table control function 14a receives an instruction to move the top board 10a in a longitudinal direction, an up-down direction, or a right-left direction from the operator through the input interface 11, thus operating a moving mechanism of the top board 10a included in the patient table 10 so as to move the top board 10a based on the received instruction.

The processing circuitry 15 includes a collection function 15a. The collection function 15a collects the NMR data on the subject S by performing various types of pulse sequences. More specifically, the collection function 15a performs the various types of pulse sequences by driving the gradient magnetic field power supply 3, the transmission circuitry 6, and the reception circuitry 7 based on sequence execution data output from the processing circuitry 17. Here, the sequence execution data indicates the pulse sequences, and is information defining a timing when the gradient magnetic field power supply 3 supplies the current to the gradient magnetic field coil 2, strength of the supplied current, a timing when the transmission circuitry 6 supplies a RF pulse signal to the whole-body RF coil 4, strength of the supplied RF pulse signal, a timing when the reception circuitry 7 samples a NMR signal, and the like. The collection function 15a receives the NMR data output from the reception circuitry 7 as a result of execution of the pulse sequences, and stores the NMR data in the storage circuitry 13. At this time, the positional information along the readout direction, the phase encoding direction, and the slice direction depending on the above-described respective gradient magnetic fields is imparted to the NMR data stored in the storage circuitry 13, and is stored as k-space data representing a two-dimensional or three-dimensional k space.

The processing circuitry 16 includes a generation function 16a. The generation function 16a generates an MR image from the NMR data collected by the collection function 15a of the processing circuitry 15. More specifically, under the control of the processing circuitry 17, the generation function 16a reads out the NMR data collected by the collection function 15a of the processing circuitry 15 from the storage circuitry 13, and performs reconstruction processing, such as Fourier transformation, on the read NMR data, thus generating a two-dimensional or three-dimensional MR image. The generation function 16a stores the generated MR image in the storage circuitry 13.

The processing circuitry 17 includes an imaging control function 17a. The imaging control function 17a controls the entire MRI apparatus 100 by controlling the components of the MRI apparatus 100. More specifically, the imaging control function 17a displays, on the display 12, a graphical user interface (GUI) for receiving input operation of various types of instructions and various types of information from the operator and controls the components of the MRI apparatus 100 based on the input operation received through the input interface 11. For example, the imaging control function 17a receives an input of an imaging condition from the operator, and sets the pulse sequences for collecting the NMR data on the subject S based on the input imaging condition. The imaging control function 17a generates the sequence execution data indicating the set pulse sequences, and outputs the sequence execution data to the processing circuitry 15, thus causing the collection function 15a of the processing circuitry 15 to perform various types of pulse sequences. For example, the imaging control function 17a controls the generation function 16a of the processing circuitry 16 to reconstruct the MR image from the k-space data collected by the processing circuitry 15. For example, the imaging control function 17a reads out the MR image stored in the storage circuitry 13 in response to a request from the operator, and displays the read MR image on the display 12.

The above-described plurality of pieces of processing circuitry 14 to 17 are realized by, for example, respective processors. In this case, the processing function of each piece of the processing circuitry are stored in the storage circuitry 13, for example, in a form of a program executable by a computer. Each piece of the processing circuitry reads out the program from the storage circuitry 13 and executes the program to realize the processing function corresponding to the program. In other words, each piece of the processing circuitry includes the processing function illustrated in FIG. 1 in a state of reading out the program.

In this example, each piece of the processing circuitry 14 to 17 is realized by a single processor; however, the exemplary embodiment is not limited thereto. For example, each piece of the processing circuitry may be configured with a combination of a plurality of independent processors, and the processing functions may be realized when each of the processors executes the program. The processing function held by each piece of the processing circuitry may be realized by being appropriately distributed or integrated into a single or plurality of pieces of processing circuitry. In the above description, the single piece of storage circuitry 13 stores the programs corresponding to the respective processing functions; however, the exemplary embodiment is not limited thereto. For example, a plurality of pieces of storage circuitry is dispersedly arranged for each piece of processing circuitry, and each piece of the processing circuitry may read out the corresponding program from each piece of storage circuitry.

The configuration example of the MRI apparatus 100 according to the present exemplary embodiment has been described above. In such a configuration, the MRI apparatus 100 according to the present exemplary embodiment includes a superconducting magnet as the static magnetic field magnet 1 that generates a static magnetic field in the imaging space where the subject S is disposed.

The superconducting magnet provided in the MRI apparatus generally includes, in addition to a vacuum container and a superconducting coil, a radiation shield for reducing heat penetration into the superconducting coil.

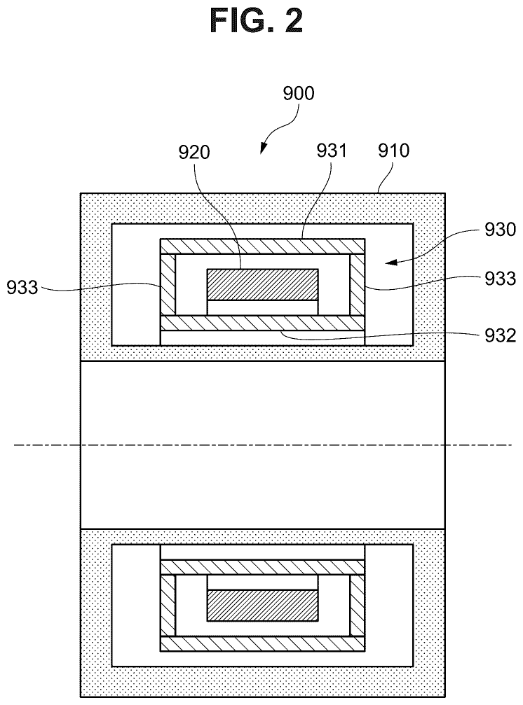

FIG. 2 is a diagram illustrating a superconducting magnet 900 according to a comparative example of the first exemplary embodiment.

For example, as illustrated in FIG. 2, the superconducting magnet 900 provided in the MRI apparatus includes a vacuum container 910, a superconducting coil 920, and a radiation shield 930.

The vacuum container 910 is a container formed in a cylindrical shape, and internally houses the superconducting coil 920, thereby providing vacuum insulation to the superconducting coil 920 from the outside.

The superconducting coil 920 includes a superconducting wire material wound around the axis of the superconducting magnet 900, and is energized in a superconducting state, thus generating a static magnetic field.

The radiation shield 930 is formed in a hollow cylindrical shape including an outer cylinder 931 and an inner cylinder 932, disposed between the vacuum container 910 and the superconducting coil 920, and covers the superconducting coil 920 with the outer cylinder 931 and the inner cylinder 932.

More specifically, the radiation shield 930 includes the outer cylinder 931, the inner cylinder 932, and two annular side plates 933 with which both ends of the outer cylinder 931 and the inner cylinder 932 are closed, and houses the superconducting coil 920 in a space between the outer cylinder 931 and the inner cylinder 932.

For example, the entire radiation shield 930 including the outer cylinder 931, the inner cylinder 932, and the side plates 933 is made of a metal, such as aluminum and copper, and is maintained at an intermediate temperature (20 K to 77 K) to reduce heat penetration into the superconducting coil from the vacuum container at a room temperature.

In such a configuration in which the superconducting magnet provided in the MRI apparatus includes the radiation shield, when the gradient magnetic field coil disposed inside the superconducting magnet is excited, an eddy current occurs in the radiation shield by a variable magnetic field generated from the gradient magnetic field coil. The eddy current may cause heat generation in the superconducting coil, or results in artifacts in an image.

More specifically, when the eddy current occurs in the radiation shield, the radiation shield vibrates due to action of excitation force by interaction with the static magnetic field generated by the superconducting coil. This vibration causes the radiation shield to serve as a heat generation source, and accordingly the superconducting coil may generate heat. In a case where the radiation shield is made of a metal having a low electric resistivity, such as aluminum and copper, the eddy current remains for a long time, so that the magnetic field generated by the eddy current may induce artifacts in an image.

Thus, in the MRI apparatus 100 according to the present exemplary embodiment, the superconducting magnet provided as the static magnetic field magnet 1 is configured to reduce the eddy current occurring in the radiation shield.

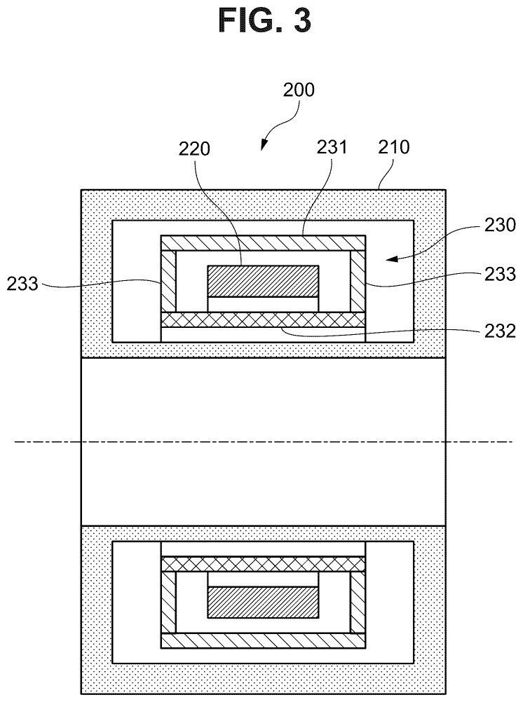

FIG. 3 is a diagram illustrating an example of a superconducting magnet 200 according to the first exemplary embodiment.

For example, as illustrated in FIG. 3, the superconducting magnet 200 according to the present exemplary embodiment includes a vacuum container 210, a superconducting coil 220, and a radiation shield 230.

The vacuum container 210 is a container formed in a cylindrical shape, and internally houses the superconducting coil 220, thereby providing vacuum insulation to the superconducting coil 220 from the outside.

The superconducting coil 220 is made of a superconducting wire material wound around the axis of the superconducting magnet 200, and is energized in a superconducting state, thus generating a static magnetic field.

The radiation shield 230 is formed in a hollow cylindrical shape including an outer cylinder 231 and an inner cylinder 232, disposed between the vacuum container 210 and the superconducting coil 220, and covers the superconducting coil 220 with the outer cylinder 231 and the inner cylinder 232.

More specifically, the radiation shield 230 includes the outer cylinder 231, the inner cylinder 232, and two annular side plates 233 that closes both ends of the outer cylinder 231 and the inner cylinder 232, and houses the superconducting coil 220 in a space between the outer cylinder 231 and the inner cylinder 232.

In the present exemplary embodiment, the outer cylinder 231 and the side plates 233 of the radiation shield 230 are made of a metal, such as aluminum and copper, and are maintained at an intermediate temperature (20 K to 77 K) to reduce heat penetration into the superconducting coil 220 from the vacuum container at a room temperature. For example, the outer cylinder 231 and the side plates 233 are made of pure aluminum (A1050, A1070, in Japanese Industrial Standards [JIS] etc.), or oxygen-free copper (C1020 in JIS).

In the present exemplary embodiment, at least a part of the inner cylinder 232 of the radiation shield 230 is made of fiber reinforced plastics (FRP). Here, FRP is an example of an insulator or a high-resistance material. For example, the inner cylinder 232 is made of glass fiber reinforced plastics (GFRP), or carbon fiber reinforced plastics (CFRP).

As described above, the radiation shield 230 according to the present exemplary embodiment is not entirely made of a metal as in the radiation shield 930 according to the comparative example illustrated in FIG. 2. The outer cylinder 231 and the side plates 233 are made of a metal, and at least a part of the inner cylinder 232 is made of FRP.

In the configuration in which the gradient magnetic field coil is disposed inside the superconducting magnet as in the present exemplary embodiment, the inner cylinder is normally dominant in a portion of the radiation shield where an eddy current occurs. Thus, as in the radiation shield 230 according to the present exemplary embodiment, at least a part of the inner cylinder 232 is made of FRP, which significantly reduces the occurrence of the eddy current in the radiation shield 230.

Thus, according to the first exemplary embodiment, it is possible to reduce the occurrence of the eddy current in the radiation shield 230 while maintaining cooling performance that is a role of the radiation shield 230. Reduction in the occurrence of the eddy current in the radiation shield 230 controls vibration and the magnetic field of the radiation shield 230 resulting from the eddy current, thus reducing heat generation in the superconducting coil and the occurrence of an artifact in an image.

The first exemplary embodiment has been described above. In the above-described superconducting magnet 200, the radiation shield 230 is disposed in an extremely narrow space. Thus, the shape of the radiation shield is restricted, and design reflecting therein an assembly procedure is demanded.

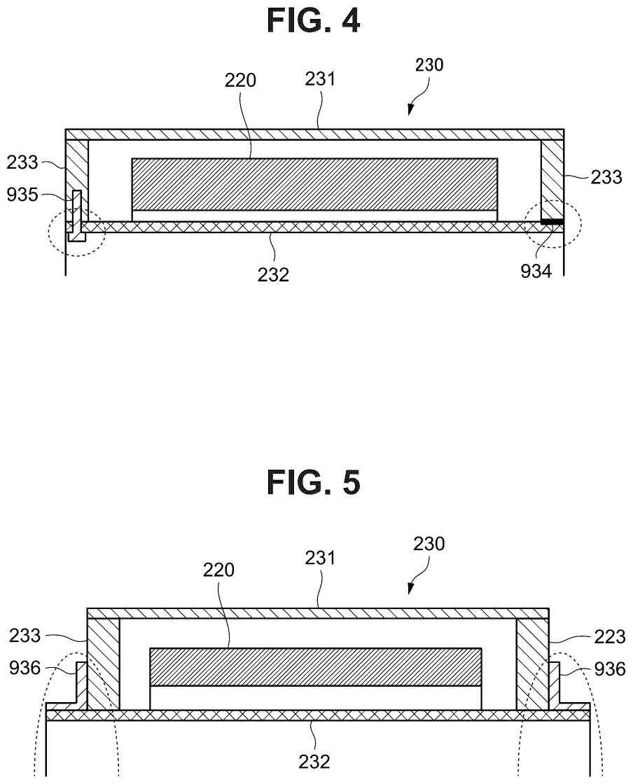

FIGS. 4 to 6 are diagrams each illustrating restriction on the radiation shield 230 according to the first exemplary embodiment.

For example, as illustrated in FIG. 4, the radiation shield 230 generally has a thickness of about several millimeters. Thus, it is difficult to secure a joining surface 934 having a sufficient area between the inner cylinder 232 and the side plates 233. As illustrated in FIG. 4, in a case where the inner cylinder 232 and the side plates 233 are fastened with bolts 935, screw holes are to be provided near ends of the inner cylinder 232; however, the forming of such holes in portions made of FRP may break the ends.

In the superconducting magnet 200 provided in the MRI apparatus 100, it is required that the radiation shield 230 has no unnecessary irregularities in order to increase a boar diameter and to shorten a bore length. For example, as illustrated in FIG. 5, in a case where fastening parts 936 are provided at the ends of the inner cylinder 232, and the inner cylinder 232 and the side plates 233 are fastened via the fastening parts 936, the inner cylinder 232 protrudes in the axis direction.

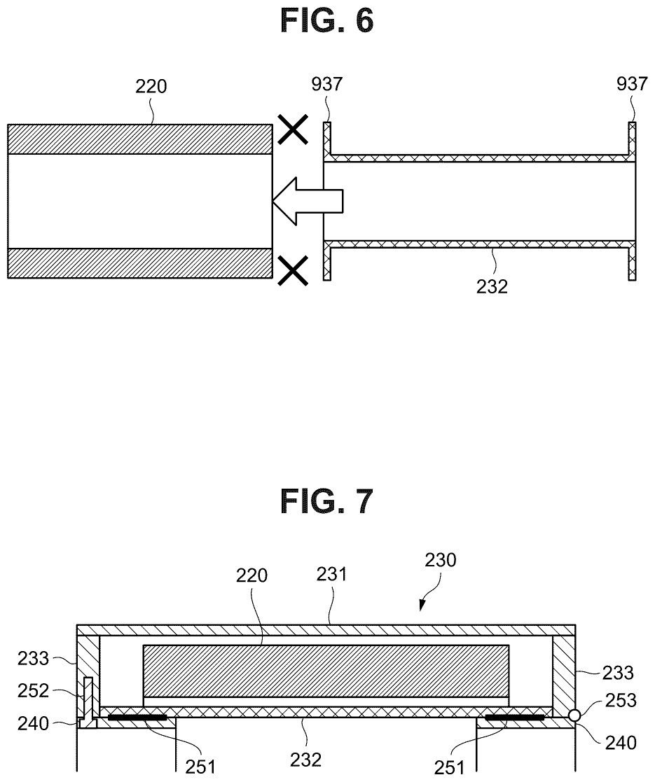

For example, as illustrated in FIG. 6, in a case where ribs 937 to be fastened with the side plates 233 are integrally provided at the ends of the inner cylinder 232, the ribs 937 may interfere with the superconducting coil 220, and assembly may be impossible.

Thus, in the following, examples of the radiation shield 230 with such restriction on the shape and the assembly procedure reflected are described as second to eighth exemplary embodiments. In the following exemplary embodiments, differences from the above-described first exemplary embodiment are mainly described, and detailed descriptions of configurations common to the above-described exemplary embodiment are omitted.

### Second Exemplary Embodiment

FIG. 7 is a diagram illustrating an example of the radiation shield 230 according to the second exemplary embodiment.

For example, in the present exemplary embodiment, the radiation shield 230 further includes two annular coupling rings 240 disposed at both ends of the inner cylinder 232, and the inner cylinder 232 is fixed to the side plates 233 via the coupling rings 240, as illustrated in FIG. 7.

In the present exemplary embodiment, the coupling rings 240 are made of a metal. For example, the coupling rings 240 are made of any of an aluminum alloy, stainless steel, and copper. For example, the coupling rings 240 are made of an aluminum alloy (A5083 in JIS, etc.) or stainless steel (SUS304 and SUS316 in JIS, etc.).

With such a configuration, it is possible to secure joining surfaces 251 having sufficient areas for the coupling rings 240 and the inner cylinder 232. When the coupling rings 240 are made of a metal, screw holes are providable near ends of the coupling rings 240.

For example, in the present exemplary embodiment, the coupling rings 240 and the inner cylinder 232 are bonded on the joining surfaces 251. A method of fixing the coupling rings 240 and the inner cylinder 232 is not limited to bonding; for example, the coupling rings 240 and the inner cylinder 232 may be fixed by press fitting or cooling fitting.

In the present exemplary embodiment, the coupling rings 240 and the respective side plates 233 are fixed by bolt fastening with bolts 252 or welding 253 at the ends of the coupling rings 240. A method of fixing the coupling rings 240 and the respective side plates 233 is not limited to bolt fastening and welding, and the coupling rings 240 and the respective side plates 233 may be fixed by, for example, bonding with an adhesive such as epoxy resin, or rivet fastening with rivets.

### Third Exemplary Embodiment

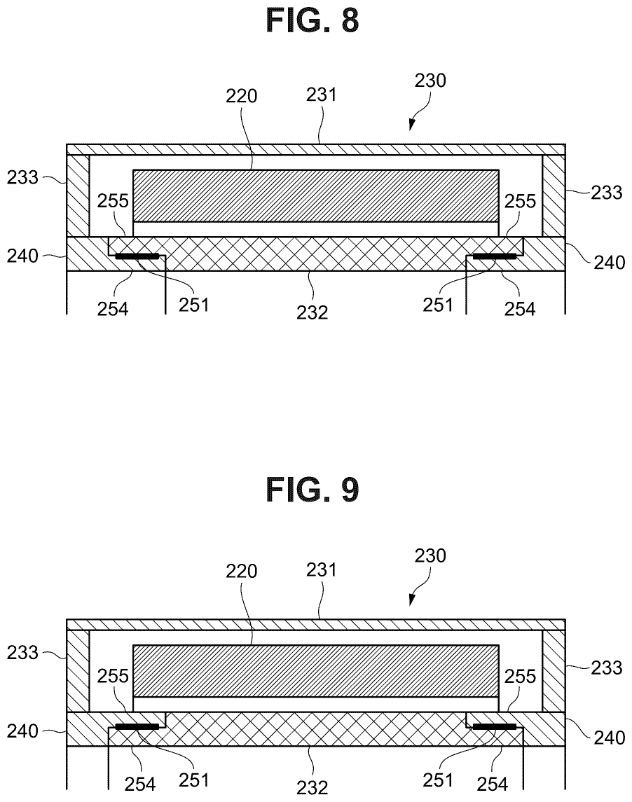

FIG. 8 and FIG. 9 are diagrams each illustrating an example of the radiation shield 230 according to the third exemplary embodiment.

For example, as illustrated in FIG. 8 and FIG. 9, in the present exemplary embodiment, the coupling rings 240 and the inner cylinder 232 are each formed in a stepped shape including a step in the radial direction, and stepped parts 254 of the coupling rings 240 and stepped parts 255 of the inner cylinder 232 are fitted to each other. Thus, the coupling rings 240 and the inner cylinder 232 are fixed without a step at joining parts.

Here, FIG. 8 illustrates an example in a case where the stepped shape of the inner cylinder 232 is formed by an inside of the inner cylinder 232 being cut. In this case, the coupling rings 240 are each formed in a shape in which the inside protrudes toward the inner cylinder 232 so as to be fitted to cut parts in the inside of the inner cylinder 232.

FIG. 9 illustrates an example in a case where the stepped shape of the inner cylinder 232 is formed by an outside of the inner cylinder 232 being cut. In this case, the coupling rings 240 are each formed in a shape in which the outside protrudes toward the inner cylinder 232 so as to be fitted to cut parts in the outside of the inner cylinder 232.

Such a configuration enables control of increase in thickness at the joining parts between the coupling rings 240 and the inner cylinder 232.

### Fourth Exemplary Embodiment

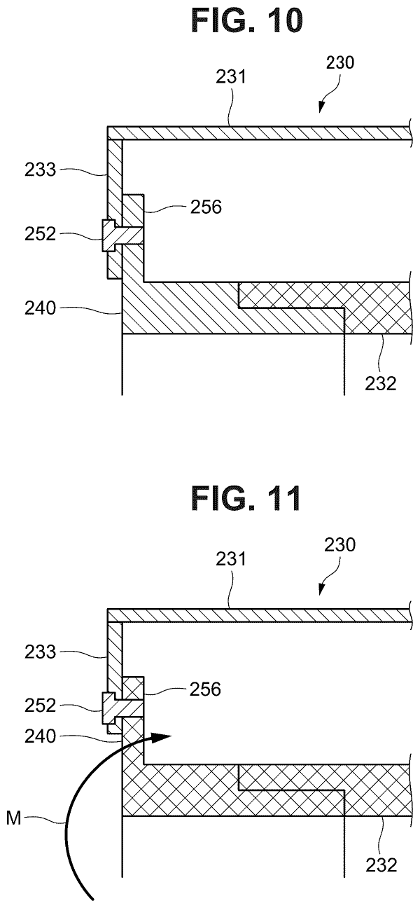

FIG. 10 is a diagram illustrating an example of the radiation shield 230 according to the fourth exemplary embodiment.

For example, in the present exemplary embodiment, each of the coupling rings 240 includes an annular rib 256 outwardly protruding in the radius direction, at the end, and the rib 256 and the corresponding side plate 233 are fixed by bolt fastening with the bolts 252, as illustrated in FIG. 10. The method of fixing the ribs 256 of the coupling rings 240 and the respective side plates 233 is not limited to bolt fastening, and the ribs 256 of the coupling rings 240 and the respective side plates 233 may be fixed by, for example, bonding with an adhesive such as an epoxy resin, welding, or rivet fastening with rivets.

With such a configuration, the ribs 256 are provided on the coupling rings 240, so that the coupling rings 240 and the respective side plates 233 are easily fixed by bonding, welding, bolt fastening, rivet fastening, or the like even with the side plates 233 having a thin thicknesses.

### Fifth Exemplary Embodiment

FIG. 11 is a diagram illustrating an example of the radiation shield 230 according to the fifth exemplary embodiment.

For example, in the present exemplary embodiment, as in the fourth exemplary embodiment, each of the coupling rings 240 includes the annular rib 256 outwardly protruding in the radius direction, at the end, and the rib 256 and the corresponding side plate 233 are fixed by any of bonding, bolt fastening, and rivet fastening, as illustrated in FIG. 11.

In the present exemplary embodiment, the coupling rings 240 and the ribs 256 are made of FRP.

With such a configuration, a part of a side surface of the radiation shield 230 is configured by the ribs 256 made of FRP, thus reducing the eddy current resulting from a variable magnetic field M reaching from the side plate 233 side.

### Sixth Exemplary Embodiment

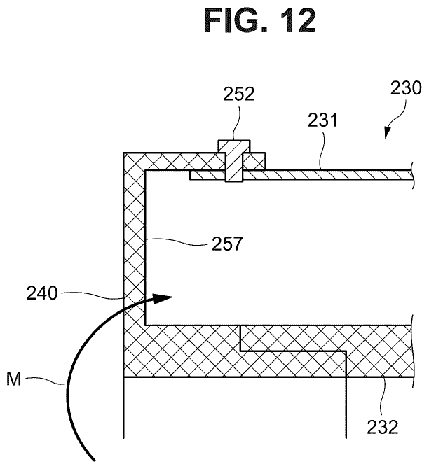

FIG. 12 is a diagram illustrating an example of the radiation shield 230 according to the sixth exemplary embodiment.

For example, in the present exemplary embodiment, the side plates 233 are omitted, and the inner cylinder 232 of the radiation shield 230 is fixed to the outer cylinder 231 via the coupling rings 240, as illustrated in FIG. 12.

In the present exemplary embodiment, each of the coupling rings 240 includes, at its end, an annular rib 257 that outwardly protrudes in the radial direction and extends up to the outer cylinder 231. The rib 257 and the outer cylinder 231 are fixed by bolt fastening with the bolts 252. A method of fixing the ribs 257 of the coupling rings 240 and the outer cylinder 231 is not limited to bolt fastening, and the ribs 257 of the coupling rings 240 and the outer cylinder 231 may be fixed by, for example, bonding with an adhesive such as an epoxy resin, or rivet fastening with rivets.

In the present exemplary embodiment, the coupling rings 240 and the ribs 257 are made of FRP.

With such a configuration, the entire side surfaces of the radiation shield 230 are configured by the ribs 257 made of FRP, thus further reducing the eddy current resulting from the variable magnetic field M reaching from the side plate 233 side.

### Seventh Exemplary Embodiment

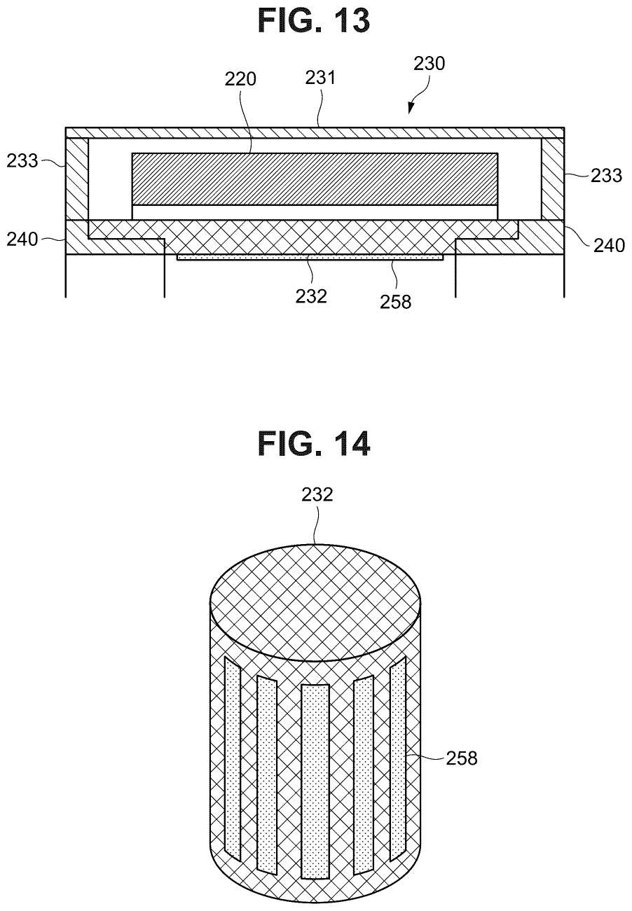

FIG. 13 and FIG. 14 are diagrams each illustrating an example of the radiation shield 230 according to the seventh exemplary embodiment.

For example, in the present exemplary embodiment, a plurality of strip-like metal sheets 258 is bonded to a portion of the inner cylinder 232 made of FRP, in parallel to the axis direction of the inner cylinder 232, as illustrated in FIG. 13 and FIG. 14. For example, the metal sheets 258 are made of a high-purity aluminum foil.

Here, the plurality of metal sheets 258 is arranged at intervals in a circumferential direction of the inner cylinder 232 so as not to be connected to the coupling rings 240 and the side plates 233 made of a metal, so that the eddy current is divided. The plurality of metal sheets 258 may be bonded to the inner peripheral surface of the inner cylinder 232 as illustrated in FIG. 13, or may be bonded to the outer peripheral surface of the inner cylinder 232 as illustrated in FIG. 14.

With such a configuration, the metal sheets 258 are bonded to the inner cylinder 232 made of FRP, thus improving cooling performance of the radiation shield 230.

### Eighth Exemplary Embodiment

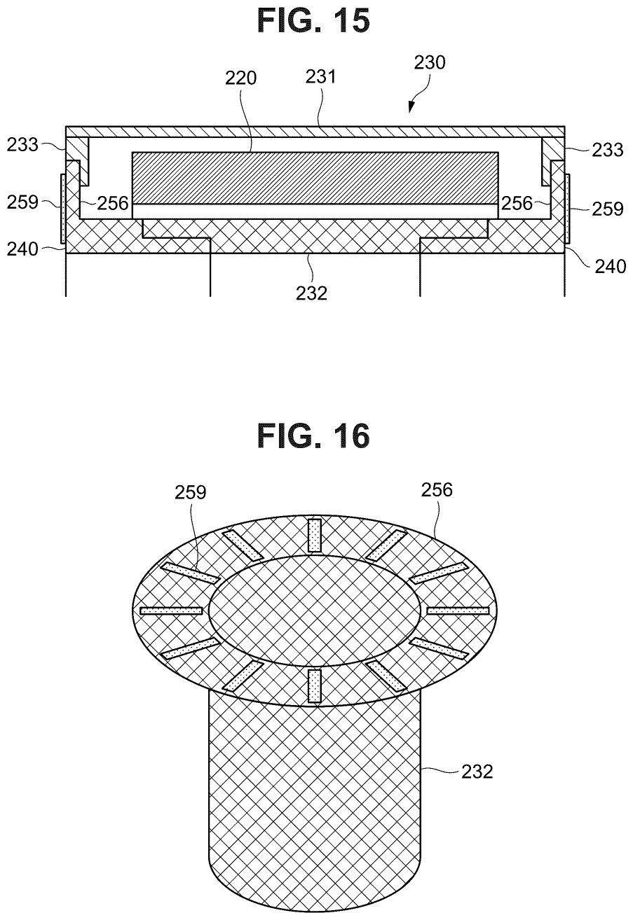

FIG. 15 and FIG. 16 are diagrams each illustrating an example of the radiation shield 230 according to the eighth exemplary embodiment.

For example, in the present exemplary embodiment, as in the fifth exemplary embodiment, each of the coupling rings 240 includes, at its end, the annular rib 256 outwardly protruding in the radial direction. The coupling rings 240 and the ribs 256 are made of FRP as illustrated in FIG. 15 and FIG. 16.

In the present exemplary embodiment, a plurality of strip-like metal sheets 259 are bonded to a surface of the rib 256 included in each of the coupling rings 240, to extend in the radial direction of the rib 256. For example, the metal sheets 259 are made of a high-purity aluminum foil.

Here, the plurality of metal sheets 259 is arranged at intervals in the circumferential direction of the rib 256 so as not to be connected to the corresponding side plate 233 made of a metal, so that the eddy current is divided. The plurality of metal sheets 259 may be bonded to the outer surface of the rib 256 as illustrated in FIG. 15, or bonded to the inner surface of the rib 256.

With such a configuration, the metal sheets 259 are bonded to the ribs 256 of the coupling rings 240 made of FRP, thus improving cooling performance of the radiation shield 230.

According to the above-described second to eighth exemplary embodiments, the inner cylinder 232 made of FRP and the outer cylinder 231 or the side plates 233 made of a metal can be joined with a minimum space by using the coupling rings 240.

According to the above-described second to eighth exemplary embodiments, the coupling rings 240 and the inner cylinder 232 are provided separately from each other. Therefore, interference with the superconducting coil 220 does not occur during assembly.

According to the above-described seventh and eighth exemplary embodiments, the radiation shield 230 can be uniformly cooled by the outer cylinder 231 made of the metal, and the metal sheets 258 or 259 bonded to the coupling rings 240 or the inner cylinder 232 made of FRP. This makes it possible to maintain the original function as the radiation shield.

The superconducting magnet 200 according to the above-described exemplary embodiments is a so-called high-temperature superconducting magnet in which the radiation shield 230 is maintained at the intermediate temperature (20 K to 77 K). The high-temperature superconducting magnet can maintain the superconducting state at a high temperature as compared with a superconducting magnet using liquid helium. Therefore, sufficient cooling performance can be maintained even with the radiation shield 230 including the inner cylinder 232 made of FRP as in an above-described exemplary embodiment.

The above-described radiation shield 230 is not limited to the high-temperature superconducting magnet, and even when the radiation shield 230 is applied to a low-temperature superconducting magnet using liquid helium, the cooling performance can be maintained. In particular, the radiation shield 230 described in each of the seventh and eighth exemplary embodiments can be uniformly cooled by the outer cylinder 231, and the metal sheets 258 or 259 bonded to the inner cylinder 232 or the coupling rings 240. Thus, the radiation shield 230 can maintain sufficient cooling performance even in the low-temperature superconducting magnet.

In the above-described exemplary embodiments, the example in the case where at least a part of the inner cylinder 232 of the radiation shield 230 is made of FRP; however, the exemplary embodiments are not limited thereto. For example, at least a part of the inner cylinder 232 of the radiation shield 230 may be made of an insulator or a high-resistance material other than FRP.

In the present specification, the high-resistance material means a material having a resistivity 20 times or more a resistivity (about 6×10⁻⁷ [Ωm]) of stainless steel (SUS304 in JIS). Examples of the high-resistance material in the present specification include CFRP described above. CFRP has a property of changing in the resistivity depending on a fiber direction. The resistivity in a direction in which the resistivity is the smallest is about 1×10⁻⁵ [Ωm], and the resistivity in a direction in which the resistivity is the largest is about 1×10⁻¹ [Ωm]. The eddy current normally flows so as to draw a loop. CFRP has characteristics that the eddy current is unlikely to occur because of such anisotropy of the resistivity, as compared with a uniform material having a resistivity of about 1×10⁻⁵ [Ωm]. Therefore, in the case where at least a part of the inner cylinder 232 of the radiation shield 230 is made of CFRP, the eddy current occurring in the radiation shield can be more effectively reduced.

In the above description, the example in which the “processor” reads out the programs corresponding to the respective processing functions from the storage circuitry, and executes the programs is described; however, the exemplary embodiments are not limited thereto. The term “processor” means, for example, a central processing unit (CPU), a graphics processing unit (GPU), or circuitry such as an application specific integrated circuit (ASIC) and a programmable logic device (e.g., simple programmable logic device (SPLD), complex programmable logic device (CPLD), and field programmable gate array (FPGA)). In a case where the processor is, for example, a CPU, the processor realizes the processing functions by reading out the programs stored in the storage circuitry and executing the programs. In a case where the processor is an ASIC, the processing functions are directly incorporated as logic circuitry in circuitry of the processor in place of storing the programs in the storage circuitry. Each of the processors according to the exemplary embodiments is not limited to being configured as single piece of circuitry, and a plurality of pieces of independent circuitry may be combined to configure a single processor and realize the processing function thereof. Further, the plurality of components illustrated in FIG. 1 may be integrated to a single processor to realize the processing functions thereof.

The program to be executed by the processor is provided by being previously incorporated in a read only memory (ROM), storage circuitry, or the like. The program may be provided by being stored in a computer-readable storage medium such as a compact disk (CD)-ROM, a flexible disk (FD), a CD-recordable (CD-R), and a digital versatile disk (DVD), as a file in a format that can be installed in or executed by the apparatus. The program may be stored in a computer connected to a network such as the Internet, and may be provided or distributed by being downloaded through the network. For example, the program is configured by modules including the above-described functional units. As actual hardware, the CPU reads out and executes the program from a storage medium such as a ROM, to load the modules to a main storage device, and the modules are generated on a main storage device.

In the foregoing exemplary embodiments and modifications, the components of the apparatuses illustrated in the diagrams are functional concepts and do not necessarily need to be physically configured as illustrated in the diagrams. In other words, the specific forms of distribution or integration of the apparatuses are not limited to the illustrated ones, and all or part of the apparatuses can be functionally or physically distributed or integrated into any units depending on various loads and usages. All or part of the processing functions for the apparatuses to perform can be implemented by a CPU and programs to be analyzed and executed by the CPU, or as wired logic hardware.

All or part of the processes described to be automatically performed in the foregoing exemplary embodiments can be manually performed. All or part of the processes described to be manually performed can be automatically performed using known methods. Furthermore, the processing procedures, control procedures, specific names, and information including various types of data and parameters described above or illustrated in the drawings can be freely modified unless otherwise specified.

According to the at least one exemplary embodiment described above, it is possible to reduce the eddy current occurring in the radiation shield.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A superconducting magnet used in a magnetic resonance imaging apparatus, the superconducting magnet comprising:
a superconducting coil made of a wound superconducting wire material; and
a cylindrical radiation shield including an outer cylinder and an inner cylinder, the outer cylinder and the inner cylinder covering the superconducting coil,
wherein the outer cylinder of the radiation shield is made of a metal, and at least a part of the inner cylinder of the radiation shield is made of an insulator or a high-resistance material.

2. The superconducting magnet according to claim 1, wherein the radiation shield further includes annular coupling rings disposed at both ends of the inner cylinder, and the inner cylinder is fixed to the outer cylinder or annular side plates that close both ends of the outer cylinder and the inner cylinder, via the coupling rings.

3. The superconducting magnet according to claim 2, wherein the coupling rings and the inner cylinder are fixed by any of bonding, press fitting, and cooling fitting.

4. The superconducting magnet according to claim 2, wherein the coupling rings and the side plates are fixed by any of bonding, welding, bolt fastening, and rivet fastening.

5. The superconducting magnet according to claim 2, wherein the coupling rings and the inner cylinder each have, at an end, a stepped shape including a step in a radial direction, and step parts of the coupling rings and step parts of the inner cylinder are fitted to be fixed without a step at joining parts.

6. The superconducting magnet according to claim 2, wherein each of the coupling rings has an annular rib at an end, and the ribs and the side plates are fixed by any of bonding, welding, bolt fastening, and rivet fastening.

7. The superconducting magnet according to claim 2, wherein each of the coupling rings includes an annular rib at an end, and the ribs and the outer cylinder are fixed by any of bonding, welding, bolt fastening, and rivet fastening.

8. The superconducting magnet according to claim 2, wherein the coupling rings are made of any of an aluminum alloy, stainless steel, and copper.

9. The superconducting magnet according to claim 6, wherein the coupling rings and the ribs are made of fiber reinforced plastics.

10. The superconducting magnet according to claim 7, wherein the coupling rings and the ribs are made of fiber reinforced plastics.

11. The superconducting magnet according to claim 9, wherein a plurality of strip-like metal sheets is bonded to a surface of the rib of each of the coupling rings, to extend in a radial direction of the rib.

12. The superconducting magnet according to claim 2, wherein a plurality of strip-like metal sheets is bonded to a portion of the inner cylinder made of the insulator or the high-resistance material, in parallel to an axis direction of the inner cylinder.

13. A magnetic resonance imaging apparatus comprising the superconducting magnet according to claim 1 as a static magnetic field magnet configured to generate a static magnetic field in an imaging space where a subject is placed.
